(19) United States
(12) Patent Application Publication
(10) Pub. No.: US 2016/0071536 A1
(43) Pub. Date: Mar. 10, 2016

(54) ADJUSTMENT METHOD OF PARAMETERS OF MULTISTAGE NOTCH FILTER

(71) Applicant: KABUSHIKI KAISHA TOSHIBA, Tokyo (JP)

(72) Inventors: Yoshiyuki Ishihara, Kawasaki Kanagawa (JP); Shinji Takakura, Yokohama Kanagawa (JP)

(21) Appl. No.: 14/635,745

(22) Filed: Mar. 2, 2015

Related U.S. Application Data
(60) Provisional application No. 62/048,649, filed on Sep. 10, 2014.

(51) Int. Cl. G11B 5/596; G11B 20/10; H03J 7/02

(52) U.S. Cl. CPC G11B 5/59627; H03J 7/02; G11B 20/10046

(57) ABSTRACT

According to one embodiment, a method of adjusting parameters set of a multistage notch filter includes calculating a first value which is a square sum of an error between a frequency response characteristic of a reference notch filter and a frequency response characteristic of the notch filter in evaluation points of a low-frequency band, calculating a second value which is a square sum of an amount in which an open-loop gain response characteristic which is series coupling of the object and the controller is protruded from an inverse gain response characteristic of the notch filter in evaluation points of a high-frequency band, and adjusting the parameters by simultaneously minimizing the first and second values.

### CROSS-REFERENCE TO RELATED APPLICATIONS

This application claims the benefit of U.S. Provisional Application No. 62/048,649, filed Sep. 10, 2014, the entire contents of which are incorporated herein by reference.

### FIELD

Embodiments described herein relate generally to a method of adjusting parameters of a multistage notch filter.

### BACKGROUND

Recently, feedback control for controlling a voice coil motor (VCM) to be controlled object by a signal obtained by filtering a position error signal of a head of a magnetic disk is applied in position control of the head.

Although phase delay compensation and phase lead compensation are used for such filtering for position control of the head, a multistage notch filter is sometimes used to suppress a signal of a mechanical resonant frequency component present in a controlled object. The multistage notch filter must adjust three parameters of a frequency, depth and width in accordance with the mechanical resonant characteristic of the controlled object.

### BRIEF DESCRIPTION OF THE DRAWINGS

FIG. 1 is an exemplary block diagram showing a configuration of a main part of a magnetic disk apparatus according to an embodiment.

FIG. 2 is an exemplary block diagram showing a configuration of a head positioning feedback control system according to the embodiment.

FIG. 3 is an exemplary function block diagram of an adjustment program.

FIG. 4 is an exemplary flowchart showing procedures of adjusting a frequency, depth and width of a multistage notch filter by the adjustment program.

FIG. 5 is an exemplary function block diagram of a frequency response characteristic measuring unit.

FIG. 6 is an exemplary flowchart showing procedures of measuring a frequency response characteristic of controlled object.

FIG. 7 is an exemplary figure for describing frequency response characteristic data of controlled object.

FIG. 8 is an exemplary figure for describing frequency response characteristic data of a positioning feedback controller.

FIG. 9 is an exemplary figure for describing open-loop frequency response characteristic data.

FIG. 10 is an exemplary block diagram showing a configuration of a genetic algorithm processor.

FIG. 11 is an exemplary flowchart showing procedures of adjusting frequency, depth and width of a multistage notch filter by a genetic algorithm.

FIG. 12 is an exemplary figure for describing a frequency separating a low-frequency band and a high-frequency band.

FIG. 13 is an exemplary figure for describing a first objective function value.

FIG. 14 is an exemplary figure for describing a second objective function value.

FIG. 15 is an exemplary figure for describing ranking of slave individuals.

FIG. 16 is an exemplary figure for describing a situation in which a range where the slave individuals are generated is constricted due to the parameter T reduced as generations of the genetic algorithm progress.

FIG. 17A, FIG. 17B, FIG. 17C and FIG. 17D are exemplary figures showing an open-loop gain response characteristic and an inverse gain response characteristic of a notch filter calculated from parameters of a group of slave individuals.

### DETAILED DESCRIPTION

In general, according to one embodiment, an adjustment method of parameters of a multistage notch filter regarding to a controlled object, in a head positioning control system of a magnetic disk apparatus. The method comprises calculating a first objective function value which is a square sum of an error between a reference notch filter having a reference transfer characteristic of a notch filter in a low-frequency band and a frequency response characteristic of the multistage notch filter in a plurality of evaluation points of the low-frequency band of a plurality of evaluation points set from 0 Hz to a sampling frequency, calculating a second objective function value which is a square sum of an amount in which an open-loop gain response characteristic which is series coupling of the controlled object and the positioning feedback controller is protruded from an inverse gain response characteristic of the multistage notch filter drawn from a set robust stability evaluation reference line in a plurality of evaluation points of a high-frequency band of the plurality of evaluation points, and adjusting the parameters by simultaneously minimizing the first objective function value and the second objective function value.

[Configuration of Disk Drive]

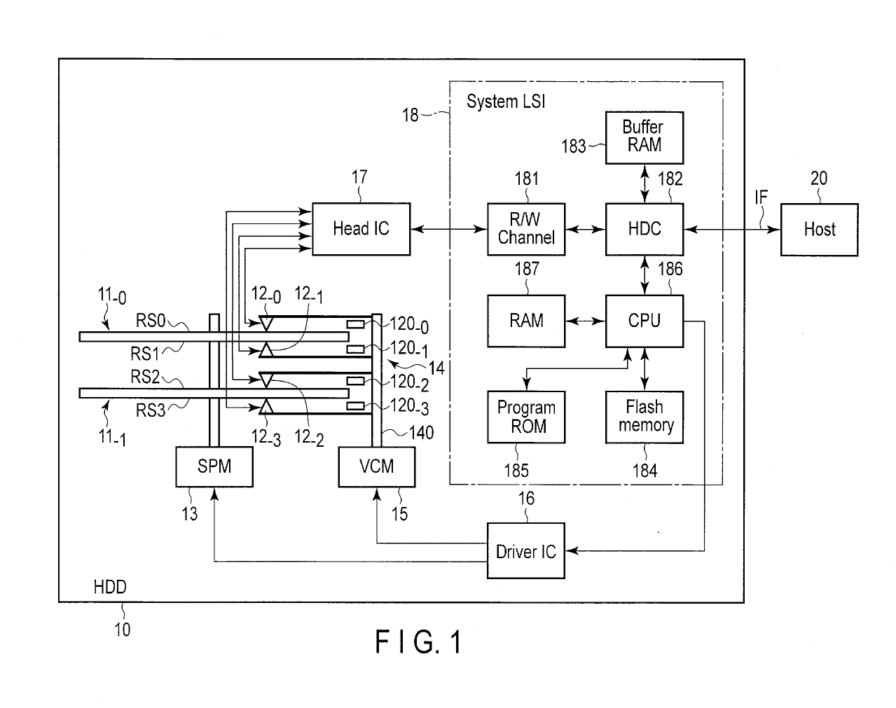

FIG. 1 is a block diagram showing a configuration of a main part of a hard disk drive (HDD) 10 as a magnetic disk apparatus of this embodiment.

A host 20 uses the HDD 10 as a memory device of the host 20. The host 20 is connected to the HDD 10 by a host interface IF.

The HDD 10 comprises disks (magnetic disk) 11-0 and 11-1, heads (magnetic heads) 12-0 to 12-3, a spindle motor (SPM) 13, an actuator 14, a voice coil motor (VCM) 15, a driver IC 16, a head IC 17 and a system LSI 18.

The disks 11-0 and 11-1 are magnetic recording media, and are laminated and arranged in regular intervals. Each of disks 11-0 and 11-1 includes upper and lower disk surfaces. In this embodiment, both of the disk surfaces are recording surfaces on which data is magnetically recorded. That is, disk 11-0 includes recording surfaces RS0 and RS1, and disk 11-1 includes recording surfaces RS2 and RS3.

The disks 11-0 and 11-1 are rotated by the SPM 13 at high speed. The SPM 13 is driven by a driving current (or driving voltage) supplied from the driver IC 16. It should be noted that the HDD 10 may comprise a single disk or at least three disks.

The heads 12-0 and 12-1 are arranged in accordance with recording surfaces RS0 and RS1 situated over and under the disk 11-0, respectively. The heads 12-2 and 12-3 are arranged in accordance with recording surfaces RS2 and RS3 situated on the top of and underneath disk 11-1, respectively. The heads 12-0 to 12-3 and corresponding recording surfaces RS0 to RS3 are identified by head numbers 0 (H0) to 3 (H3). Each of the heads 12-0 to 12-4 comprises a read element and a write element. Each of the heads 12-0 and 12-1 is used for writing data to recording surfaces RS0 and RS1 of disk 11-0 and reading data from recording surfaces RS0 and RS1. Each of the heads 12-2 and 12-3 is used for writing data to recording surfaces RS2 and RS3 of disk 11-1 and reading data from recording surfaces RS2 and RS3.

Heads 12-0 to 12-3 are attached to a tip of the actuator 14. More specifically, heads 12-0 to 12-3 are attached to a tip of a suspension extending from four arms of the actuator 14. Such a structure of the suspension comprising head 12-j (j=0, 1, 2, 3) is called a head gimbal assembly (HGA). That is, head 12-j is attached to the arms of the actuator 14 in the form of the HGA.

The actuator 14 is swingably supported around a pivot 140. The actuator 14 comprises the VCM 15. The VCM 15 is used as a drive source of the actuator 14. The VCM 15 is driven by the driving current (or driving voltage) supplied from the driver IC 16, and swings the actuator 14 around the pivot 140. This causes head 12-j attached to each arm of the actuator 14 to move toward a radial direction of disk 11-i (i=0, 1).

Ramps 120-0 and 120-1 are arranged in a position out of recording surfaces RS0 and RS1 of disk 11-0, for example, a position adjacent to an outer periphery of disk 11-0. Similarly, ramp 120-2 and 120-3 are arranged in a position out of recording surfaces RS2 and RS3 of disk 11-1, for example, a position adjacent to an outer periphery of disk 11-1. The position of ramp 120-j (j=0, 1, 2, 3) is also a position on a transfer path of the HGA including head 12-j (more specifically, a lift tab of a tip of the HGA). Ramp 120-j provides a saving area (parking area) for saving the HGA including head 12-j while the HDD 10 is in a non-operating state.

The driver IC 16 drives the SPM 13 and the VCM 15 in accordance with the control of a central processing unit (CPU) 186, which will be described later, in the system LSI 18. The head IC 17 amplifies a signal read by head 12-j (read signal). The head IC 17 also converts write data transferred from an R/W channel 181, which will be described later, in the system LSI 18 into a write current, and output it to head 12-j.

The system LSI 18 is an LSI called a system-on-a-chip (SOC), in which a plurality of elements are accumulated on a single chip. The system LSI 18 comprises the read/write channel (R/W channel) 181, a hard disk controller (HDC) 182, a buffer RAM 183, a flash memory 184, a program ROM 185, the CPU 186 and a RAM 187.

The R/W channel 181 is a signal processing device which processes a group of signals relevant to reading/writing. The R/W channel 181 digitalizes a read signal, and decodes read data from the digitalized data. The R/W channel 181 also extracts servo data necessary for positioning head 12-j from the digital data. The R/W channel 181 also encodes write data.

The HDC 182 is connected to the host 20 through the host interface IF. The HDC 182 receives a command transferred from the host 20 (right command, read command, etc.). The HDC 182 controls data transfer between the host 20 and the HDC 182. The HDC 182 controls data transfer between disk 11-i and the HDC 182.

The buffer RAM 183 comprises a buffer area for temporarily storing data read from data to be written to disk 11-i and disk 11-i through the head IC 17 and the R/W channel 181.

The flash memory 184 is a rewritable non-volatile memory.

The program ROM 185 stores a control program (firmware) or an adjustment program. It should be noted that the control program or the adjustment program may be stored in a partial area of the flash memory 184. The control program is a program used after shipment. The adjustment program automatically adjusts a frequency, depth and width as parameters of a multistage filter, which will be described later, before shipment.

The CPU 186 functions as a main controller of the HDD 10. The CPU 186 controls at least another part of an element in the HDD 10 in accordance with the control program or the adjustment program stored in the program ROM 185. A partial area of the RAM 187 is used as a working area of the CPU 186.

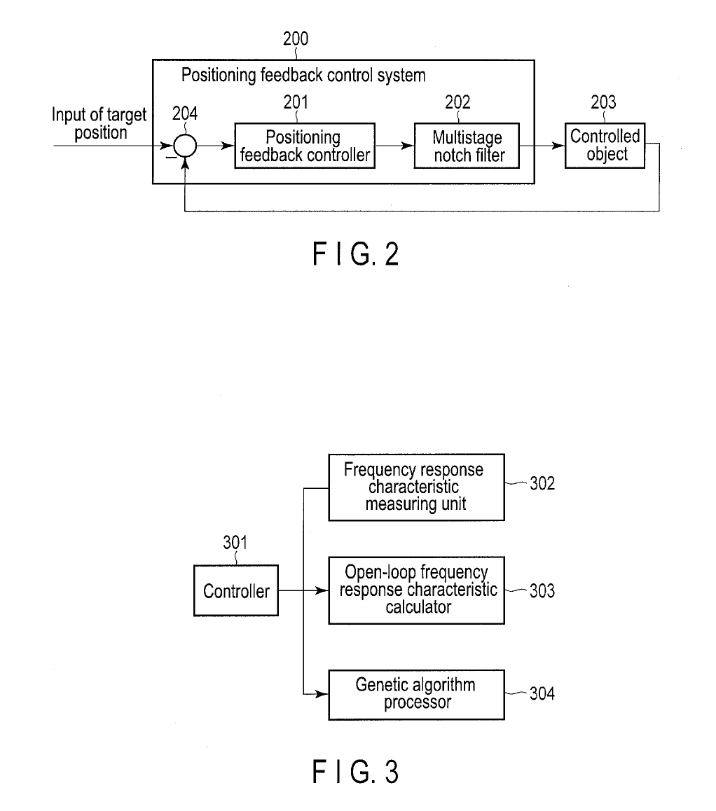

The HDD 10 includes a head positioning feedback control system which executes position control processing of heads (12-0 to 12-3). FIG. 2 is a block diagram showing a configuration of head positioning feedback control system.

A head positioning feedback control system 200 comprises a positioning feedback controller 201, a multistage notch filter 202, an error detector 204, etc. The positioning feedback controller 201, the multistage notch filter 202 and a controlled object 203 are connected in series.

A transfer characteristic from a voice coil motor (VCM) to a head position is the controlled object 203, and an observation signal of a feedback system is a signal of the head position. The controlled object 203 includes at least one of the voice coil motor 15, the arms of the actuator 14 and the head gimbal assembly. The error detector 204 detects a position error signal of the head position relative to a center of a target track (target position). The position error signal is input to the positioning feedback controller 201. The positioning feedback controller 201 comprises a phase delay compensator of general low frequency compensation (integral element) and a phase lead compensator for securing stability margin (proportional element and differential element).

The positioning feedback controller 201 executes phase delay compensation and phase lead compensation to an input position error signal, and generates a control input. The control input is input to the multistage notch filter 202. The multistage notch filter 202 removes a component which is included in the controlled object 203 and corresponds to a resonant frequency from the control input. This prevents a control system from being unstable by mechanical resonant excitation of the head gimbal assembly (arms, suspension, etc.).

In the multistage notch filter 202, a control input signal after the component corresponding to the resonant frequency is removed is provided to the controlled object 203, and accordingly, a head position is controlled. The observation signal of the feedback system (signal of head position) is detected from the controlled object 203, and input to the error detector 204.

Next, an adjustment program which automatically adjusts three parameters of a frequency, depth and width set to the multistage notch filter 202 will be described.

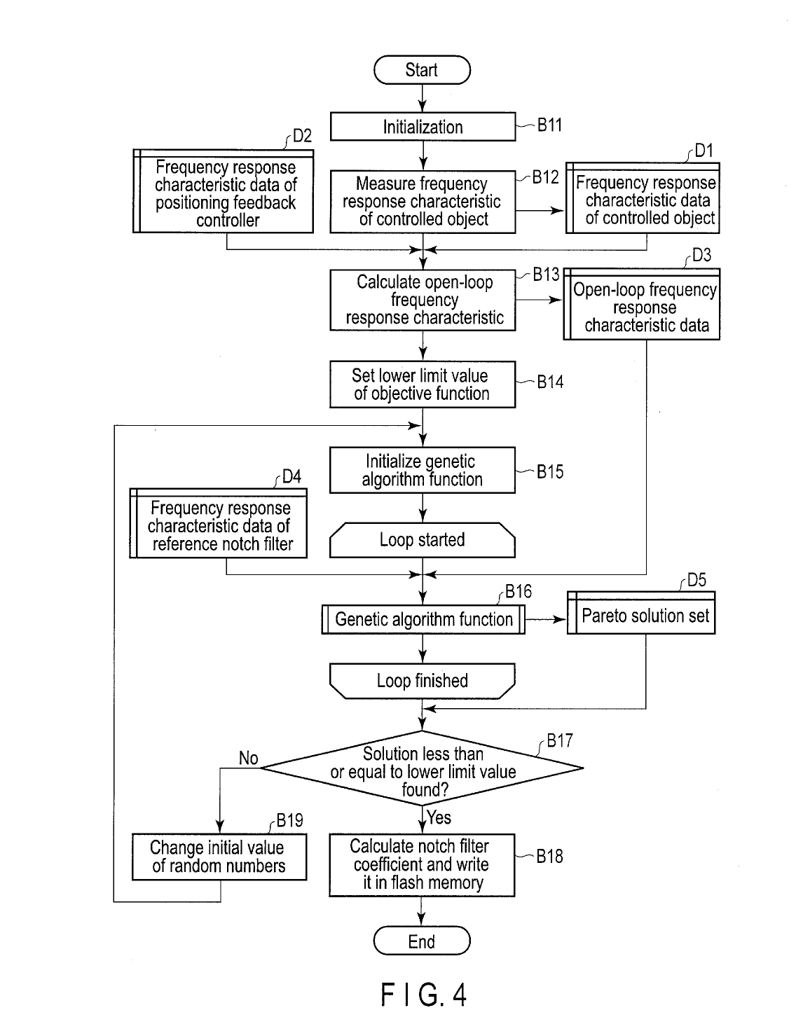

FIG. 3 is a function block diagram of the adjustment program. As shown in FIG. 3, the adjustment program comprises a controller 301, a frequency response characteristic measuring unit 302, an open-loop frequency response characteristic calculator 303 and a genetic algorithm processor 304.

The controller 301 is configured to totally control the adjustment program. The frequency response characteristic measuring unit 302 is configured to measure (calculate) a frequency response characteristic of the controlled object 203. The frequency response characteristic is gain response (dB) to a frequency. The open-loop frequency response characteristic calculator 303 is configured to perform processing for calculating an open-loop frequency response characteristic based on the frequency response characteristic of the controlled object 203 and that of the positioning feedback controller 201.

The genetic algorithm processor 304 is configured to calculate a first objective function value which is a square sum of an error between a reference notch filter and a frequency response characteristic of a notch filter in a plurality of evaluation points of a low-frequency band of a plurality of evaluation points set from 0 Hz to a sampling frequency.

Further, the genetic algorithm processor 304 is configured to calculate a second objective function value which is a square sum of an amount in which an open-loop gain response characteristic which is series coupling of a controlled object and a positioning feedback controller is protruded from an inverse gain response characteristic of a notch filter drawn from a set robust stability evaluation reference line in a plurality of evaluation points of a high-frequency band of a plurality of evaluation points.

Further, the genetic algorithm processor 304 is configured to adjust a frequency, depth and width by simultaneously minimizing the first objective function value and the second objective function value.

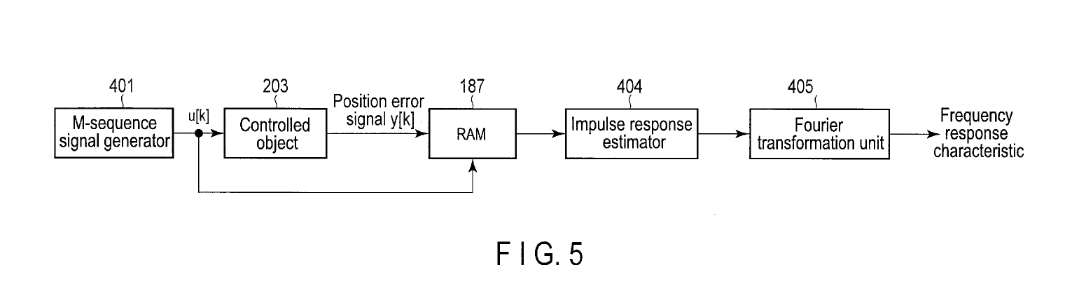

FIG. 4 is a flowchart showing an example of procedures of adjusting a frequency, depth and width of a multistage notch filter by the adjustment program.

[Initialization]

The controller 301 initializes the RAM 187 (temporary buffer) and random numbers used in a whole automatic adjustment method (B11). Further, frequency response characteristic data of the positioning feedback controller 201 saved in the flash memory 184 in advance is loaded into the RAM 187. Similarly, reference notch filter frequency response characteristic data saved in the flash memory 184 in advance is loaded into the RAM 187.

[Measurement of Frequency Response Characteristic to be Controlled]

The frequency response characteristic measuring unit 302 measures the frequency response characteristic of the controlled object 203 (B12).

Identification algorithm which measures the frequency response characteristic of the controlled object 203 uses an M-sequence signal which is a kind of pseudo random binary signal as an identification input, and a finite impulse response (FIR) model as a identification model. Further, a sampling period of an output of a controlled object needs to be an even multiple of that of an input to the controlled object as a condition. The multiplying factor is multirate ratio P.

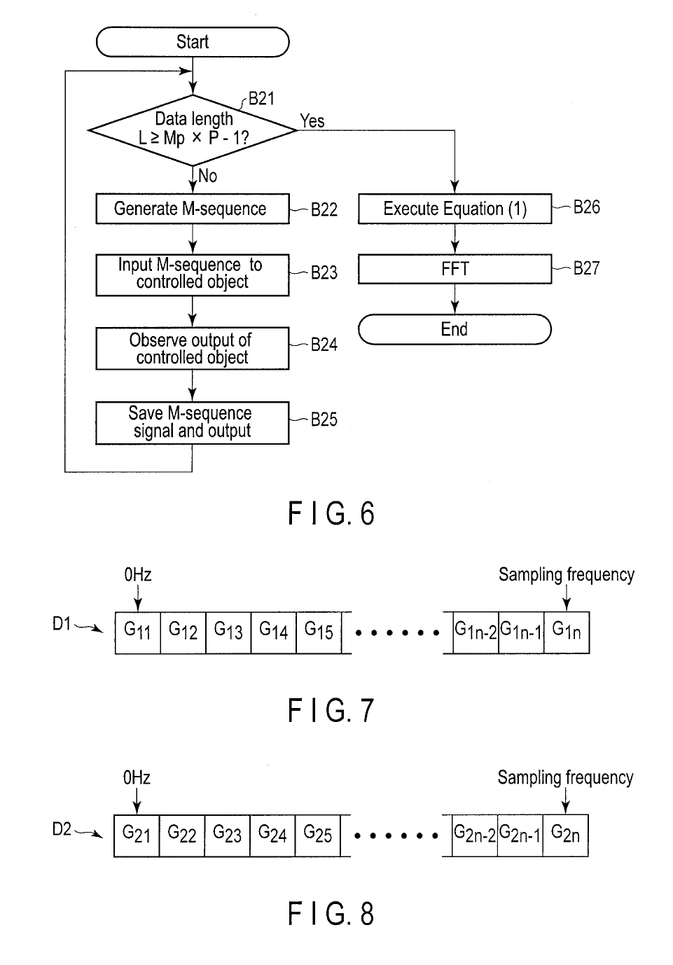

FIG. 5 is a function block diagram of the frequency response characteristic measuring unit 302 according to this embodiment.

The frequency response characteristic measuring unit 302 comprises an M-sequence signal generator 401, an impulse response estimator 404, a Fourier transformation unit 405, etc.

The M-sequence signal generator 401 generates the M-sequence signal which is a kind of pseudo random binary signal for data acquisition length L=Mp×P−1, where Mp is a period of the M-sequence signal.

Signal u[k] of each time of the generated M-sequence signal is input to the controlled object 203, and output data (position error signal y[k]) is output from the controlled object 203.

The RAM 187 stores the M-sequence signal generated by the M-sequence signal generator 401, and the output data obtained from the controlled object 203 in response to the signal of each time.

The impulse response estimator 404 calculates impulse response estimate \hat{θ} of the controlled object 203 based on the M-sequence signal and the output data stored in the RAM 187. The calculation is carried out by Equation (1).

$$\hat{θ} = \frac{( {\sum }_{l = 0}^{{M}_{p} - 1} u [ Pl ] y [ Pl ] )}{{σ}_{u}^{2}} \qquad ( 1 )$$

Where u[k] is a component of the M-sequence signal acquired by time k (k^{th}), y[k] is output data obtained when u[k] is an input of the controlled object 203, and σᵤ² is variance of u[k].

The Fourier transformation unit 405 outputs a value generated by applying discrete Fourier transformation to \hat{θ}. This value is output from the frequency response characteristic measuring unit 302 as a measurement result of the frequency response characteristic of the controlled object 203.

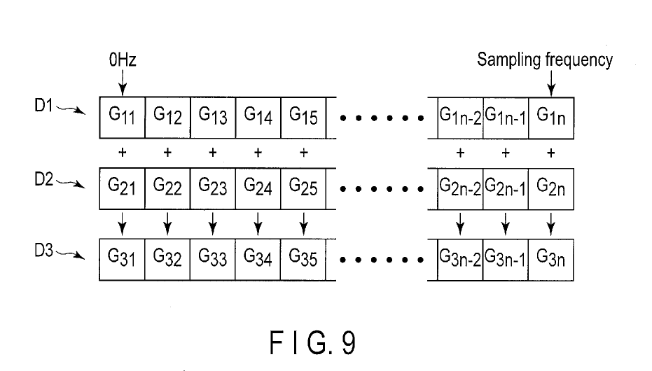

FIG. 6 is a flowchart showing an example of procedures of measuring a frequency response characteristic of a controlled object. The processing based on the execution procedures is executed in the CPU 186.

In B21, the frequency response characteristic measuring unit 302 determines whether acquired data length L has reached Mp×P−1 or not.

If data length L has not reached Mp×P−1, the M-sequence signal generator 401 generates an M-sequence signal of a next time (B22), and inputs the M-sequence signal to the controlled object 203 (B23).

The frequency response characteristic measuring unit 302 observes an output from the controlled object 203 (B24), and saves the M-sequence signal and the output data in the RAM 187 (B25). The above B21 to B25 are repeated until data length L reaches Mp×P−1.

When data length L reaches Mp×P−1, that is, when a signal and output data which correspond to data length L are acquired, the impulse response estimator 404 calculates an impulse response estimate of the controlled object 203. Specifically, the impulse response estimate of the controlled object 203 is obtained by calculating impulse response estimate \hat{θ} of a FIR model which is a identification model of the controlled object 203 by Equation (1) (B26).

Then, the Fourier transformation unit 405 applies the discrete Fourier transformation to impulse response estimate \hat{θ} (B27). The result of the discrete Fourier transformation is frequency response characteristic data of the controlled object 203.

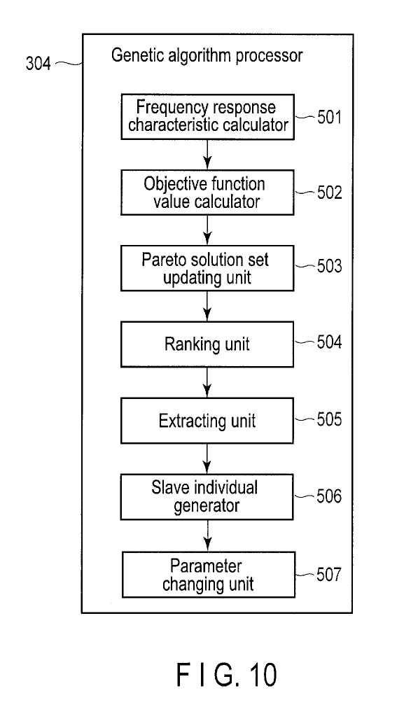

Frequency response characteristic data of n evaluation points (frequencies) set from 0 Hz to a sampling frequency is stored in the RAM 187. If n is set to a factorial of 2, for example, 1024 or 2048, discrete Fourier transformation is easily executed in the Fourier transformation unit 405. As shown in FIG. 7, frequency response characteristic data D1 of the controlled object 203 includes n controlled object frequency response characteristics (G₁₁, G₁₂, G₁₃, G₁₄, G₁₅, . . . , G₁ₙ₋₂, G₁ₙ₋₁, G₁ₙ).

[Open-Loop Frequency Response Characteristic Calculation]

Back to FIG. 4, the open-loop frequency response characteristic calculator 303 calculates an open-loop frequency response characteristic from frequency response characteristic data D2 of the positioning feedback controller 201 and frequency response characteristic data D1 of the controlled object 203 which are loaded from the flash memory 184 into the RAM 187 by initialization (B11) (B13).

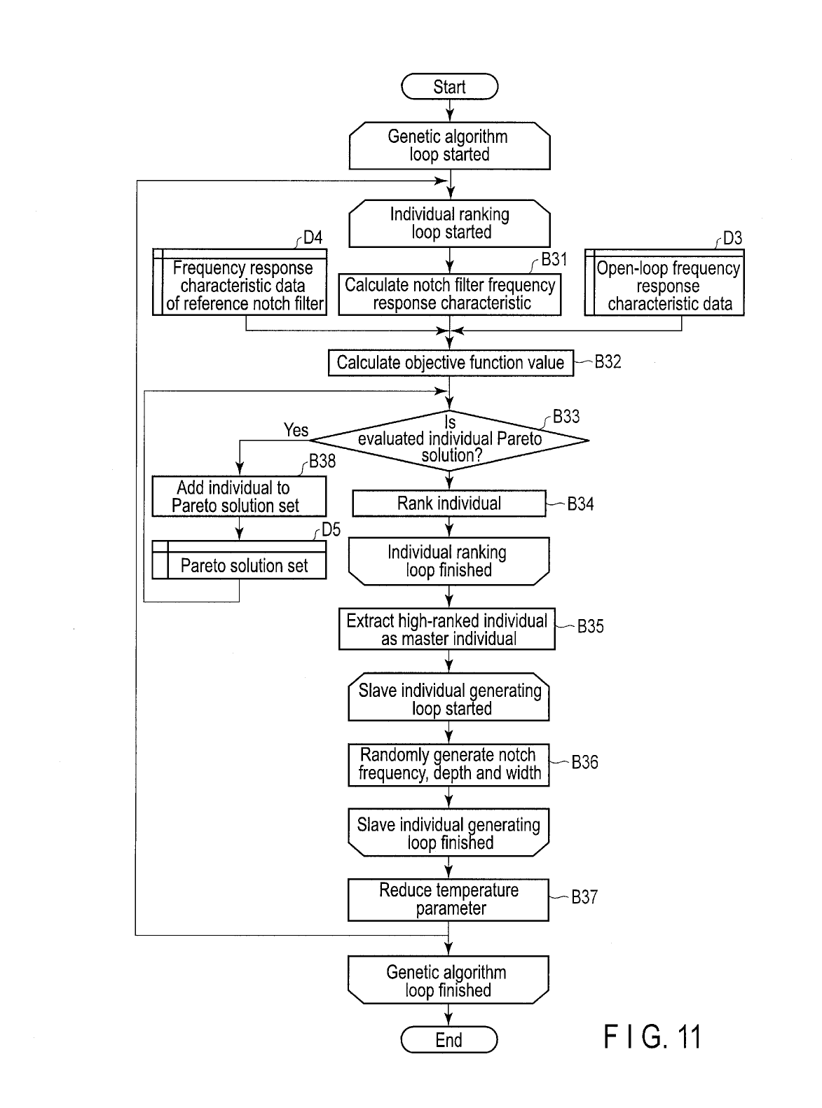

FIG. 8 shows an example of frequency response characteristic data of the positioning feedback controller 201. Frequency response characteristic data D2 of the positioning feedback controller 201 includes n frequency response characteristics (G₂₁, G₂₂, G₂₃, G₂₄, G₂₅, . . . , G₂ₙ₋₂, G₂ₙ₋₁, G₂ₙ) of the positioning feedback controller 201 set from 0 Hz to a sampling frequency.

The term “open-loop” is herein defined as series coupling of a transfer characteristic of the positioning feedback controller 201 and that of the controlled object 203. Thus, the open-loop frequency response characteristic is a sum of the frequency response characteristic of the controlled object 203 and a frequency response characteristic of the positioning feedback controller 201 (G₃₁=G₁₁ G₂₁, G₃₂=G₁₂+G₂₂, G₃₃=G₁₃+G₂₃, G₃₄=G₁₄+G₂₄, G₃₅=G₁₅+G₂₅, . . . , G₃ₙ₋₂=G₁ₙ₋₂+G₂ₙ₋₂, G₃ₙ₋₁=G₁ₙ₋₁+G₂ₙ₋₁, G₃ₙ₋₁=G₁ₙ+G₂ₙ).

The open-loop frequency response characteristic calculator 303 saves the calculated open-loop frequency response data in the RAM 187.

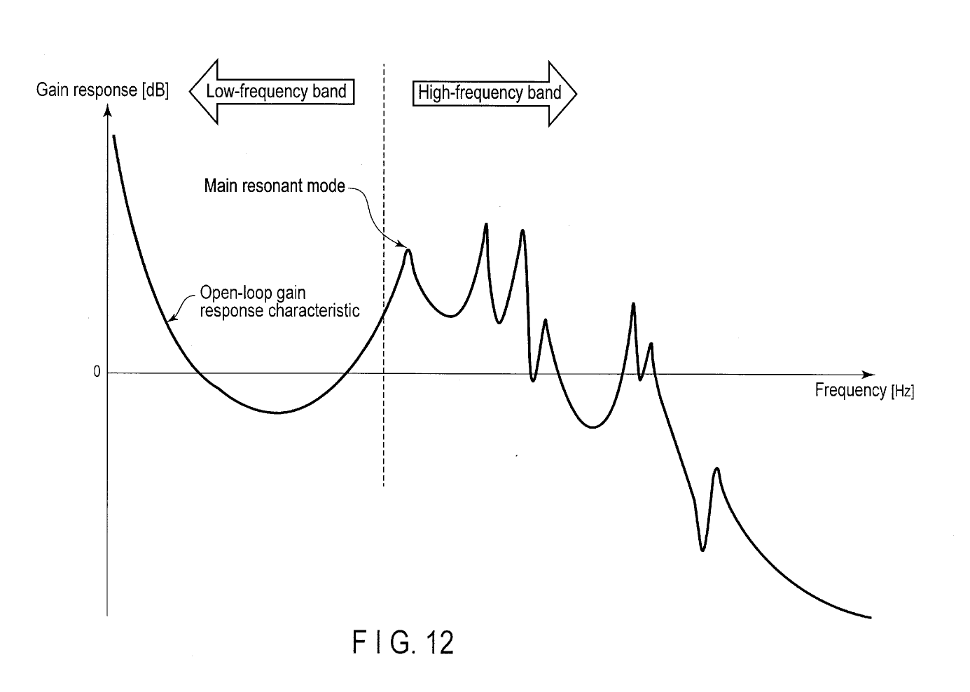

FIG. 9 shows an example of open-loop frequency response characteristic data. Open-loop frequency response characteristic data D3 includes n open-loop frequency responses (G₃₁, G₃₂, G₃₃, G₃₄, G₃₅, . . . , G₃ₙ₋₂, G₃ₙ₋₁, G₃ₙ) set from 0 Hz to a sampling frequency. As shown in FIG. 9, open-loop frequency responses G₃ᵢ (i=1, 2, 3, 4, 5, . . . , n−2, n−1, n) is a sum of G₁ᵢ and G₂ᵢ.

[Lower Limit Value Setting]

Back to FIG. 4, the controller 301 sets a lower limit value of each of the minimized first and second objective function values (B14). Although both of the first and second objective function values to be described are error square sums and should be ideally a minimum value of zero, this is difficult in real minimization in many cases. Thus, a lower limit value for determining that the first and second objective function values have been sufficiently reduced by the minimization is set, and the minimization is completed if a solution (parameter) below it is found. Preferably, positioning control of a head is executed actually using a notch filter coefficient calculated by automatically adjusted parameters, and the lower limit value is determined through trial and error by confirming whether sufficient positioning performance and a stability margin are secured.

[Genetic Algorithm Function Initialization]

The controller 301 initializes a genetic algorithm function of generating initial individuals to search for parameters of a multistage notch filter which simultaneously minimizes the first and second objective function values to be described (B15). The initialization of the genetic algorithm function includes initializing a group of individuals of the genetic algorithm and initializing temperature parameter T. The initialization of the group of individuals consists of uniformly generating random numbers within the range of upper and lower limits of each of three parameters of frequency f, depth d and width ξ, and randomly providing the three parameters for each individual. The initialization of the temperature parameter T consists of providing an initial value to the temperature parameter T.

The genetic algorithm is a kind of probabilistic search algorithm in which the evolutionary process of living things is imitated. In the genetic algorithm, a combination of parameters to be searched for is called an individual. In the genetic algorithm, an optimal parameter can be searched for by repeating an operation (generation change) of passing a feature of the individual having high fitness for an environment (objective function value) in a set of individuals (group of individuals) to a next search (next generation). It should be noted that a combination of parameters of a pair of notch filters is called an individual, and is synonymous with a solution to be described. In the genetic algorithm, several hundreds of individuals are prepared, and evaluation of the objective function value and ranking between the individuals are performed.

[Genetic Algorithm Processing]

The genetic algorithm processor 304 searches for parameters (frequency f, depth d and width ξ) optimal for the multistage notch filter 202 by the genetic algorithm (B16).

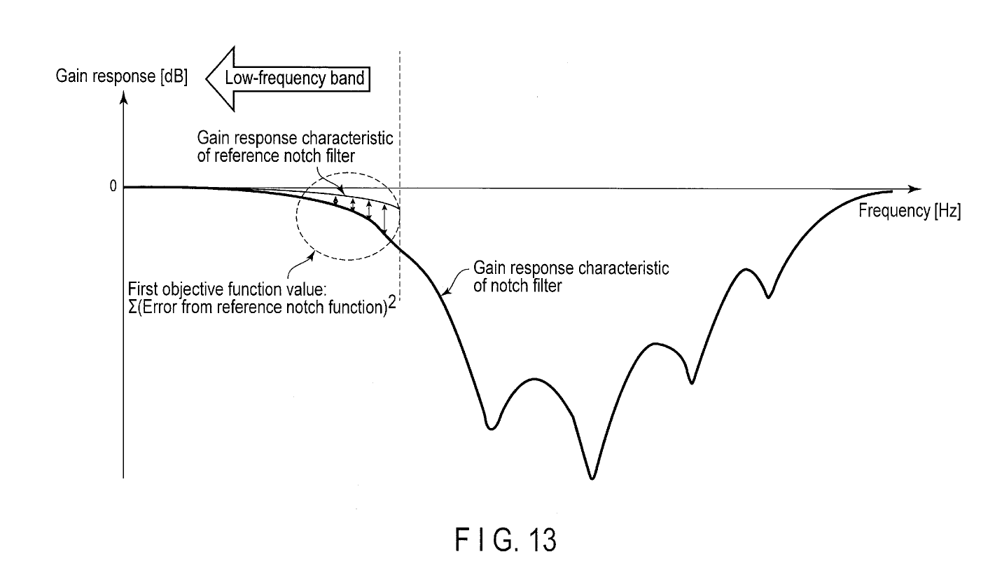

FIG. 10 is a function block diagram of the genetic algorithm processor 304.

The genetic algorithm processor 304 comprises a frequency response characteristic calculator 501, a objective function value calculator 502, a Pareto solution set updating unit 503, a ranking unit 504, an extracting unit 505, a slave individual generator 506, a parameter changing unit 507, etc.

The frequency response characteristic calculator 501 is configured to calculate a frequency response characteristic of a notch filter when the three parameters of each individual are used. The objective function value calculator 502 is configured to calculate the first and second objective function values to be described with respect to the frequency response characteristic of the notch filter calculated in the frequency response characteristic calculator 501.

The Pareto solution set updating unit 503 is configured to compare first and second objective function values of a Pareto solution in a set of Pareto solutions to be described with first and second objective function values calculated by the objective function value calculator 502, and to determine whether the first and second objective function values calculated by the objective function value calculator 502 is Pareto solutions. If the first and second objective function values calculated by the objective function value calculator 502 are determined to be the Pareto solutions, the Pareto solution set updating unit 503 is configured to add the objective function values to the set of Pareto solutions.

The ranking unit 504 is configured to check a superiority relationship between individuals based on the first objective function value and the second objective function value, and to perform ranking for each individual.

The extracting unit 505 is configured to extract, as a master individual, an individual highly ranked by the ranking unit 504. The slave individual generator 506 is configured to generate parameters (frequency f, depth d and width ξ) of a slave individual.

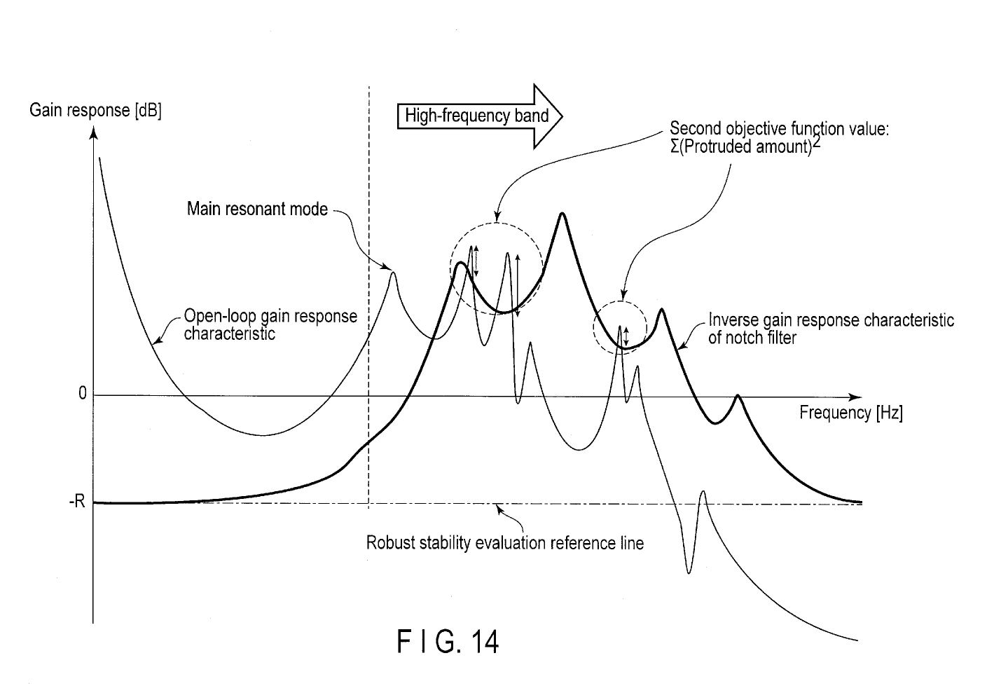

The genetic algorithm is described with reference to a flowchart of FIG. 11. FIG. 11 shows procedures of adjusting a frequency, depth and width of the multistage notch filter by the genetic algorithm.

The frequency response characteristic calculator 501 calculates a frequency response characteristic of the multistage notch filter 202 for each individual by calculating a notch filter transfer function for each individual (B31). This can be calculated by substituting z=e^{-j ω̅}i^{T}s for Equation (2), when three parameters of each individual are set as frequency f, depth d and width ξ, and each evaluation point is set as ωᵢ. It should be noted that e is the base of a natural logarithm, j is the imaginary unit and Ts is a sampling time of a positioning control system.

$$N ( z ) = \frac{( 1 - d ζ f + {f}^{2} ) {z}^{- 2} + ( 2 {f}^{2} - 2 ) {z}^{- 1} + ( 1 + d ζ f + {f}^{2} )}{( 1 - ζ f + {f}^{2} ) {z}^{- 2} + ( 2 {f}^{2} - 2 ) {z}^{- 1} + ( 1 + ζ f + {f}^{2} )} \qquad ( 2 )$$

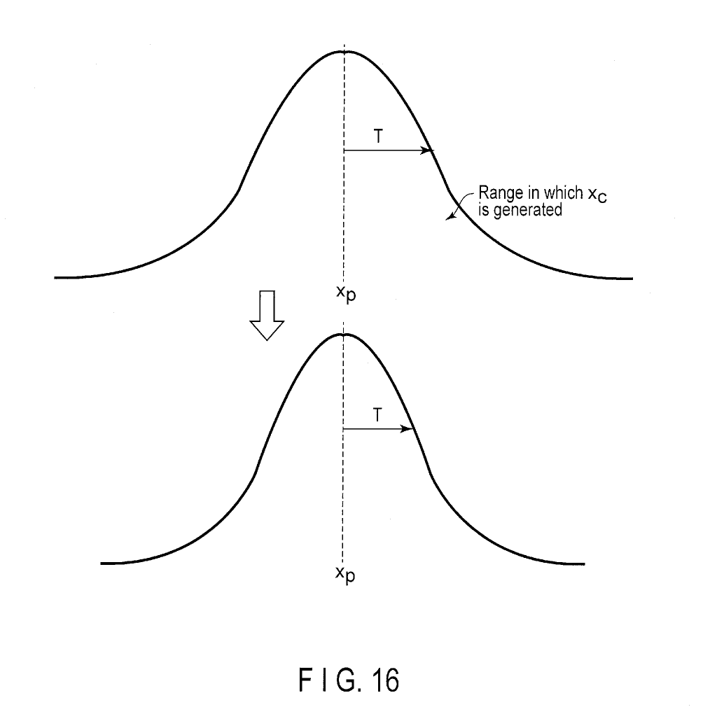

The objective function value calculator 502 calculates the first objective function value and the second objective function value from open-loop frequency response characteristic data D3 saved in the RAM 187, frequency response data D4 of the reference notch filter loaded from the flash memory 184 into the RAM 187 in the initialization (B11), and the frequency response data of the notch filter calculated in B31 (B32). The first objective function value is a square sum of an error of a frequency response. The square sum of the error of the frequency response is, for example, a square sum of an error between a frequency response of a reference notch filter in each evaluation point in a low-frequency band and a frequency response of a multistage notch filter (refer to FIG. 13).

The frequency response, described herein, is a gain (dB) and/or a phase (deg) in each evaluation point. Thus, the square sum of the error of the frequency response can be, for example, represented as follows:

Σ(gain of reference notch filter−gain of notch filter)²; or

Σ{W₁×(gain of reference notch filter−gain of notch filter)²+W₂×(phase of reference notch filter−phase of notch filter)²},

where W1 and W2 are weight coefficients and properly set.

If a gain characteristic is determined, a phase characteristic is substantially uniquely determined in terms of the characteristic of the notch filter; thus, practically, there is no substantial problem if a square sum of a gain error is applied to a first objective function. FIG. 13 shows a case where the square sum of the gain error is set as the first objective function. To more strictly make uniform characteristics in a low-frequency band of the notch filter automatically adjusted with the reference notch filter, the square sum of the phase error may be included in the first objective function. In this manner, two kinds of evaluation, that is, evaluation based on only the gain error, or based on both the gain error and the phase error, can be performed in the first objective function. Thus, the expression frequency response error is used to include both of the meanings.

The second objective function value is a square sum of an amount in which the open-loop gain response characteristic is protruded from an inverse gain response characteristic of the notch filter drawn from a robust stability evaluation reference line in each evaluation point in a high-frequency band.

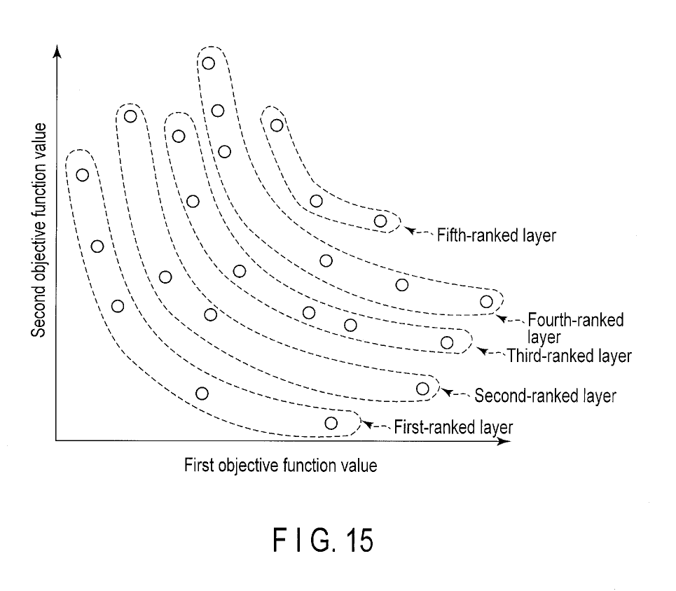

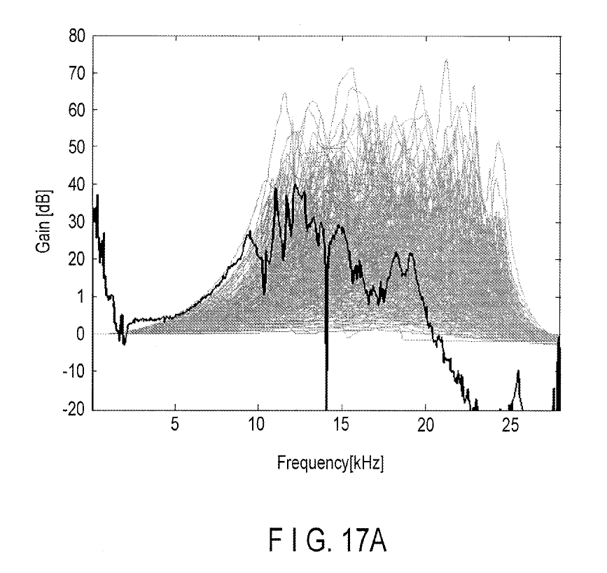

It should be noted that a target of frequency for dividing evaluation into the first objective function value (low-frequency band) and the second objective function value (high-frequency band) is frequencies slightly lower than main resonant mode frequencies of a voice coil motor, an arm and a head gimbal assembly which are controlled objects (refer to FIG. 12). Further, a robust stability evaluation reference line is a line indicating negative gain −R [dB] arbitrarily set to be 0 dB or less (refer to FIG. 14). The more negative gain −R is reduced, the more robust stability increases when a resonant peak frequency to be controlled is deviated by temperature change, etc., from that measured at the time of automatic adjustment. If it is reduced too much, the first objective function value is hard to minimize in a low-frequency band. Accordingly, an appropriate value is preferably set through trial and error. Although the robust stability evaluation reference line shown in FIG. 14 is a straight line, it may be curved or in a staircase pattern.

Positioning accuracy of a head positioning control system of a magnetic disk apparatus is determined by a sensitivity characteristic (which is a transfer characteristic indicating how much a head position responds to disturbance) in a low-frequency band having a lot of disturbance factors (external oscillation, airflow disturbance caused by disk rotation, disk oscillation, etc.). The sensitivity characteristic is determined by a transfer characteristic when the controlled object 203, the positioning feedback controller 201 and the multistage notch filter 202 are coupled in series, as shown in FIG. 2.

Generally, the transfer characteristic of the controlled object 203 has small variations in a low-frequency band, and the positioning feedback controller 201 is commonly used in all of the same models. Thus, if the transfer characteristic in a low-frequency band of the automatically adjusted notch filter can be made uniform in the all models, the positioning accuracy can also be made uniform. A notch filter having a reference transfer characteristic in a low-frequency band is called a reference notch filter. From the above, a request to make uniform the positioning accuracy in automatically adjusted all models is evaluated by the first objective function value.

Since a resonant mode to be controlled in a high-frequency band is different in each device, a positioning control system sometimes oscillates and robust stability is sometimes lost if a common notch filter is used in the all models. Then, a notch (recessed portion) frequency, depth and width of the notch filter is preferably individually adjusted for each device to cover a gain peak of the resonant mode as tightly as possible. In the automatic adjustment method of this embodiment, this request is evaluated by the second objective function value.

Further, the Pareto solution set updating unit 503 performs processing of adding a Pareto solution found in a process, in which the processing of a genetic algorithm function (B16) is repeated and generations of a group of individuals progress, to Pareto solution set D5 in the RAM 187. In reality, if a Pareto solution found before m−1 generation, that is, a Pareto solution saved in Pareto solution set D5 is compared with the first and second objective function values of an individual being evaluated in m generation, where m is a generation of a current group of individuals in the processing of a genetic algorithm function, and if it is determined that the individual being evaluated is a Pareto solution (Yes in B33), the individual is added to Pareto solution set D5 (B38).

It should be noted that since Pareto solution set D5 is empty, immediately after the processing of the genetic algorithm function (B16) is started, that is, in a first generation, an individual ranked as a first-ranked layer in individual ranking to be described (B34) is added to Pareto solution set D5.

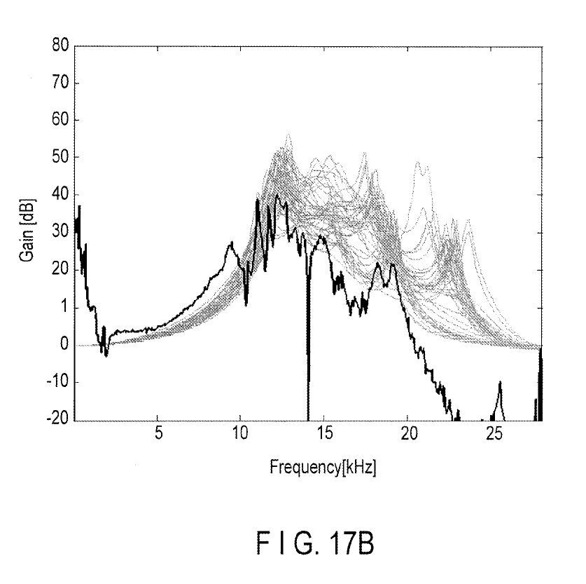

After calculation of a objective function value of each individual is completed, the ranking unit 504 checks a superiority relationship between individuals based on the first objective function value and the second objective function value, and performs ranking for each individual (B34). The ranking is described with reference to FIG. 15. When the first objective function value and the second objective function value are set for a horizontal axis and a vertical axis, respectively, and objective function values of each individual are plotted, each individual can be classified in terms of a layer based on a superiority relationship with other individuals. The layers are ranked as a first-ranked layer, a second-ranked layer, etc., in sequence from the layer closest to the origin.

The extracting unit 505 extracts an individual highly ranked in B34 as a master individual for generating a slave individual for the next generation (B35). For example, if the number of all individuals is 24 and the number of master individuals is eight, all the slave individuals of the first-ranked layer are extracted as master individuals, since five individuals are present in the first-ranked layer in FIG. 15. The other three individuals are randomly extracted from four individuals of the second-ranked layer.

The slave individual generator 506 generates parameters (frequency f, depth d and width of the slave individual for the next generation from the master individual extracted in the extracting unit 505 in accordance with Equation (3) (B36).

x_{c}=xₚ+randn(T) (3)

In Equation (3), x_{c} represents a parameter vector of a slave individual to be generated, xₚ represents a parameter vector of the master individual extracted in B35, and randn (T) represents normal distribution random numbers having standard deviation (temperature parameter) T. In the example of B35, since eight master individuals are present, two slave individuals are generated for a master individual, and 24 individuals including eight master individuals and 16 slave individuals are slave individuals for the next generation. Alternatively, three slave individuals are generated for a master individual, and 24 slave individuals can be adopted as 24 individuals for the next generation.

The parameter changing unit 507 reduces the temperature parameter T used when the slave individuals of B36 are generated in accordance with Equation (4) (B37).

Tₘ₊₁=cTₘ (4)

In Equation (4), Tₘ₊₁ represents temperature parameter of Equation (3), when a genetic algorithm function is called next, that is, in the next generation m+1, and Tₘ represents temperature parameter in current generation m. Coefficient c is preferably set approximately from 0.8 to 0.99.

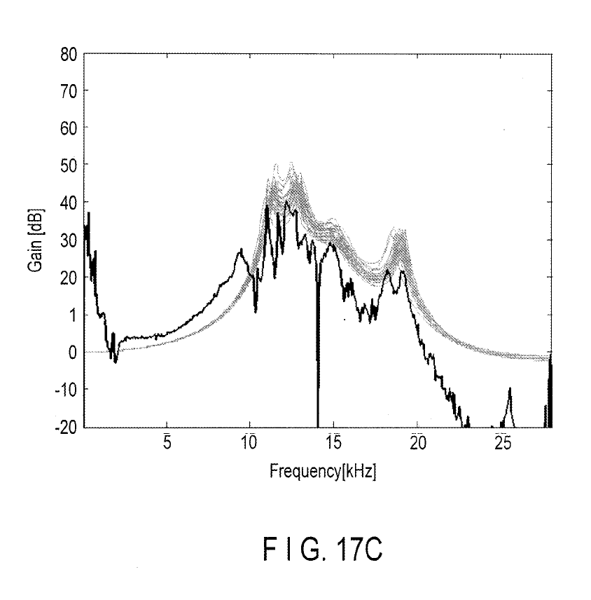

A range in which slave individuals (parameter vector x_{c}) are generated is constricted near a master individual due to the parameter T reduced as generations of the genetic algorithm progress by the processing of Equation (4) (refer to FIG. 16).

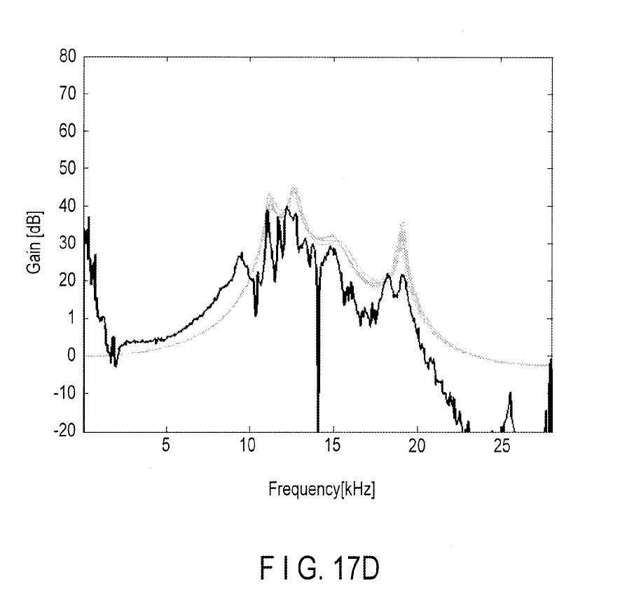

A situation in which a notch filter inverse gain characteristic of the group of slave individuals is narrowed to that tightly covering a gain peak of a resonant mode to be controlled as the generations of the genetic algorithm progress will be herein described with reference to FIGS. 17A to 17D.

FIG. 17A shows an open-loop gain response characteristic, and a notch filter inverse gain response characteristic of a first-generation group of slave individuals. Since each parameter of a group of individuals of the genetic algorithm (240 individuals) is randomly set by the initialization (B11), an individual which does not well cover the resonant peak or an individual excessively covering it is present at this moment.

FIG. 17B shows the open-loop gain response characteristic, and a notch filter inverse gain response characteristic of a sixth-generation group of slave individuals. Although the inverse gain response characteristic of the group of individuals is gradually narrowed to that covering the resonant peak of the controlled object 203, diversity of the group of individuals remains at this stage.

FIG. 17C shows the open-loop gain response characteristic, and a notch filter inverse gain response characteristic of a 72nd group of slave individuals. The inverse gain response characteristic of the group of individuals is further narrowed to that tightly covering the resonant peak of the controlled object 203.

FIG. 17D shows the open-loop gain response characteristic, and a notch filter inverse gain response characteristic of a 144th group of slave individuals. The inverse gain response characteristic of the group of individuals is narrowed substantially to that tightly covering the resonant peak. When such a state is reached, the processing of the genetic algorithm is terminated.

[Extraction of Best Solution]

Back to FIG. 4, when searching is performed predetermined times and the processing of the genetic algorithm is completed, the controller 301 determines whether solutions less than or equal to the lower limit value of the first and second objective function values set in B14 are present in Pareto solution set D5 (B17). If the solutions less than or equal to the lower limit value of the first and second objective function values set in B14 are found (Yes in B17), the controller 301 extracts a solution from them. Regarding a best solution described herein, when Pareto solution set D5 is classified in terms of a rank layer based on a superiority relationship between individuals, as shown in FIG. 15, an individual in the first-ranked layer is set to be the best if the first-ranked layer includes an individual. If the first-ranked layer includes a plurality of individuals, an individual having the smallest second objective function value (square sum of protruded amount) in them is set to be the best.

A notch filter transfer function coefficient, that is, a coefficient of z^{-q} (q=0, 1, 2) in Equation (2) is calculated from an extracted best solution, and the calculated coefficient is written in the flash memory 184 (B18).

If a solution less than or equal to the lower limit value of the first and second objective function values set in B14 cannot be found (No in B17), the controller 301 changes an initial value of random numbers (B19). Then, the processing from B15 is sequentially executed. It should be noted that if the solution less than or equal to the lower limit value of the first and second objective function values set in B14 cannot be found (No in B17), the controller 301 may relax the lower limit value of the first and second objective function values set in B14 to execute the processing from B17.

Frequency f, depth d and width are adjusted as parameters of the multistage notch filter 202 in the above processing. The multistage notch filter 202 uses the notch filter transfer function coefficient written in the flash memory 184 after shipment.

In the above embodiment, the parameters of the multistage notch filter are adjusted as described below. The first objective function value which is a square sum of an error between a reference notch filter having a reference transfer characteristic of the multistage notch filter in a low-frequency band and a frequency response characteristic of the multistage notch filter in a plurality of evaluation points of the low-frequency band of a plurality of evaluation points set from 0 Hz to a sampling frequency is calculated.

The second objective function value which is a square sum of an amount in which an open-loop gain response characteristic which is series coupling of a controlled object and a positioning feedback controller is protruded from an inverse gain response characteristic of the multistage notch filter drawn from a set robust stability evaluation reference line in a plurality of evaluation points of a high-frequency band of a plurality of evaluation points is calculated.

The parameters of the multistage notch filter are adjusted by simultaneously minimizing the calculated first and second objective function values.

An optimal parameter can be searched for by adjusting the parameters of the multistage notch filter as described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An adjustment method of adjusting parameters of a multistage notch filter regarding to a controlled object, in a head positioning control system of a magnetic disk apparatus, the method comprising:
calculating a first objective function value which is a square sum of an error between a frequency response characteristic of a reference notch filter having a reference transfer characteristic of the multistage notch filter in a low-frequency band and a frequency response characteristic of the multistage notch filter in a plurality of evaluation points of the low-frequency band of a plurality of evaluation points set from 0 Hz to a sampling frequency;
calculating a second objective function value which is a square sum of an amount in which an open-loop gain response characteristic which is series coupling of the controlled object and the positioning feedback controller is protruded from an inverse gain response characteristic of the multistage notch filter drawn from a set robust stability evaluation reference line in a plurality of evaluation points of a high-frequency band of the plurality of evaluation points; and
adjusting the parameters of the multistage notch filter by simultaneously minimizing the first objective function value and the second objective function value.

2. The method of claim 1, wherein the multistage notch filter is inserted in series with a positioning feedback controller to control the controlled object.

3. The method of claim 1, wherein the controlled object comprises a voice coil motor, an arm or a head gimbal assembly.

4. The method of claim 1, wherein the parameters comprise a frequency, depth and width.

5. The method of claim 1, wherein
genetic algorithm for generating a slave individual from a master individual in accordance with the following Equation (A) is used as a method of simultaneously minimizing the first objective function value and the second objective function value:
x_{c}=xₚ+randn(T) (A),
wherein the x_{c} represents a parameter vector of a slave individual to be generated, the xₚ represents a parameter vector of the master individual, and the randn(T) represents normal distribution random numbers having standard deviation (temperature parameter) T.

6. The method of claim 5, wherein
the parameter T of Equation (A) are reduced in accordance with the following Equation (B) as search in the genetic algorithm progresses:
Tₘ₊₁=cTₘ(c=0.8 to 0.99) (B),
wherein the Tₘ₊₁ represents temperature parameter of Equation (A) in next generation m+1, and the Tₘ represents temperature parameter in current generation m.

7. A magnetic disk apparatus comprising:
a magnetic disk;
a multistage notch filter regarding to a controlled object; and
a memory device in which parameters of the multistage notch filter are stored,
wherein the parameters of the multistage notch filter are adjusted by:
calculating a first objective function value which is a square sum of an error between frequency response characteristic of a reference notch filter having a reference transfer characteristic of the multistage notch filter in a low-frequency band and a frequency response characteristic of the multistage notch filter in a plurality of evaluation points of the low-frequency band of a plurality of evaluation points set from 0 Hz to a sampling frequency;
calculating a second objective function value which is a square sum of an amount in which an open-loop gain response characteristic which is series coupling of the controlled object and the positioning feedback controller is protruded from an inverse gain response characteristic of the multistage notch filter drawn from a set robust stability evaluation reference line in a plurality of evaluation points of a high-frequency band of the plurality of evaluation points; and
adjusting the parameters of the multistage notch filter by simultaneously minimizing the first objective function value and the second objective function value.

8. The apparatus of claim 7, further comprising a positioning feedback controller configured to control the controlled object,
wherein the multistage notch filter is inserted in series with the positioning feedback controller.

9. The apparatus of claim 7, further comprising
an arm including a head gimbal assembly;
a head provided in the head gimbal assembly and configured to write data to the magnetic disk and to read the data from the magnetic disk; and
a voice coil motor which moves the arm,
wherein the controlled object comprises the voice coil motor, the arm or the head gimbal assembly.

10. The apparatus of claim 7, wherein the parameters comprise a frequency, depth and width.

11. The apparatus of claim 7, wherein
genetic algorithm for generating a slave individual from a master individual in accordance with the following Equation (A) is used in the simultaneously minimizing the first objective function value and the second objective function value:
x_{c}=xₚ+randn(T) (A),
wherein the x_{c} represents a parameter vector of a slave individual to be generated, the xₚ represents a parameter vector of the master individual, and the randn(T) represents normal distribution random numbers having standard deviation (temperature parameter) T.

12. The apparatus of claim 11, wherein
the parameter T of Equation (A) are reduced in accordance with the following Equation (B) as search in the genetic algorithm progresses:
Tₘ₊₁=cTₘ(c=0.8 to 0.99) (B),
wherein the Tₘ₊₁ represents temperature parameter of Equation (A) in next generation m+1, and the Tₘ represents temperature parameter in current generation m.

13. A manufacturing method of a magnetic disk apparatus,
the apparatus comprising
a magnetic disk,
a multistage notch filter regarding to a controlled object,
and a memory device in which parameters of the multistage notch filter are stored,
the method comprising:
calculating a first objective function value which is a square sum of an error between a frequency response characteristic of a reference notch filter having a reference transfer characteristic of the multistage notch filter in a low-frequency band and a frequency response characteristic of the multistage notch filter in a plurality of evaluation points of the low-frequency band of a plurality of evaluation points set from 0 Hz to a sampling frequency;
calculating a second objective function value which is a square sum of an amount in which an open-loop gain response characteristic which is series coupling of the controlled object and the positioning feedback controller is protruded from an inverse gain response characteristic of the multistage notch filter drawn from a set robust stability evaluation reference line in a plurality of evaluation points of a high-frequency band of the plurality of evaluation points; and
adjusting parameters of the multistage notch filter by simultaneously minimizing the first objective function value and the second objective function value.

14. The method of claim 13, further comprising a positioning feedback controller configured to control the controlled object,
wherein the multistage notch filter is inserted in series with the positioning feedback controller.

15. The method of claim 13, wherein the apparatus further comprising
an arm including a head gimbal assembly;
a head provided in the head gimbal assembly and configured to write data to the magnetic disk and to read the data from the magnetic disk; and
a voice coil motor which moves the arm,
wherein the controlled object comprises the voice coil motor, the arm or the head gimbal assembly.

16. The method of claim 13, wherein the parameters comprise a frequency, depth and width.

17. The method of claim 13, wherein
genetic algorithm for generating a slave individual from a master individual in accordance with the following Equation (A) is used as a method of simultaneously minimizing the first objective function value and the second objective function value:
x_{c}=xₚ+randn(T) (A),
wherein the x_{c} represents a parameter vector of a slave individual to be generated, the xₚ represents a parameter vector of the master individual, and the randn(T) represents normal distribution random numbers having standard deviation (temperature parameter) T.

18. The method of claim 17, wherein
the parameter T of Equation (A) are reduced in accordance with the following Equation (B) as search in the genetic algorithm progresses:
Tₘ₊₁=cTₘ(c=0.8 to 0.99) (B),
wherein the Tₘ₊₁ represents temperature parameter of Equation (A) in next generation m+1, and the Tₘ represents temperature parameter in current generation m.
